(19) United States
(12) Patent Application Publication
(10) Pub. No.: US 2026/0083027 A1
(43) Pub. Date: Mar. 19, 2026

(54) SEMICONDUCTOR PACKAGE

(71) Applicant: SAMSUNG ELECTRONICS CO., LTD., Suwon-si (KR)

(72) Inventors: Jeonggi JIN, Suwon-si (KR); Seonghoon BAE, Suwon-si (KR); Sanghoo CHO, Suwon-si (KR); Wonho CHOI, Suwon-si (KR)

(21) Appl. No.: 19/053,141

(22) Filed: Feb. 13, 2025

(30) Foreign Application Priority Data
Sep. 13, 2024 (KR) 10-2024-0125521

(51) Int. Cl. H01L 23/498; H01L 21/48; H01L 23/00; H01L 25/18

(52) U.S. Cl. CPC H10W 90/701; H10W 70/093; H10W 70/65; H10W 90/00; H10W 90/401; H10W 70/66; H10W 90/724

(57) ABSTRACT

A semiconductor package includes a first redistribution structure, a semiconductor chip on the first redistribution structure, and a second redistribution structure on the semiconductor chip. The first redistribution structure has a first surface and an opposite second surface, and includes an insulating layer, and first redistribution conductors surrounded by the insulating layer. Bump structures are on the first surface, and include a first portion surrounded by the insulating layer and a second portion protruding from the first portion. Solder bumps are on the second portion of the bump structures. The second redistribution structure includes second redistribution conductors. The first redistribution conductors include first redistribution patterns and first redistribution vias electrically connecting the first redistribution patterns and the bump structures. The first redistribution vias have a side surface tapered toward the first surface, and the second portion of the bump structures has a side surface tapered away from the first surface.

### CROSS-REFERENCE TO RELATED APPLICATION(S)

This application claims benefit of priority to Korean Patent Application No. 10-2024-0125521, filed on Sep. 13, 2024 in the Korean Intellectual Property Office, the disclosure of which is incorporated herein by reference in its entirety.

### BACKGROUND

The present inventive concept relates to a semiconductor package.

As electronic devices become lighter and high-performance, the development of semiconductor packages having a fine pitch of input/output terminals formed therein may also be required. When a semiconductor package is surface mounted on a module substrate, main board, or the like, via solder bumps, a short circuit may occur between the solder bumps arranged in response to the fine pitch of the input/output terminals, which may limit the design of the fine pitch of the input/output terminals and solder bumps.

### SUMMARY OF THE INVENTION

An aspect of the present inventive concept is to provide a semiconductor package having improved reliability.

According to an aspect of the example embodiment, provided is a semiconductor package, the semiconductor package including a first redistribution structure having a first surface and an opposite second surface, wherein the first redistribution structure includes an insulating layer and a plurality of first redistribution conductors at least partially surrounded by the insulating layer; a plurality of bump structures on the first surface of the first redistribution structure, wherein each of the plurality of bump structures includes a first portion surrounded by the insulating layer, and a second portion protruding from the first portion in a direction away from the first surface of the first redistribution structure; a plurality of solder bumps, each of the plurality of solder bumps on the second portion of the plurality of bump structures; a semiconductor chip on the second surface of the first redistribution structure, wherein the semiconductor chip includes a plurality of connection pads electrically connected to the plurality of first redistribution conductors; a plurality of through-vias positioned around the semiconductor chip, wherein the plurality of through-vias are electrically connected to the plurality of first redistribution conductors; a mold layer sealing the semiconductor chip and the plurality of through-vias; and a second redistribution structure on the mold layer, wherein the second redistribution structure includes a plurality of second redistribution conductors electrically connected to the plurality of through-vias, wherein the plurality of first redistribution conductors include a plurality of first redistribution patterns and a plurality of first redistribution vias electrically connecting the plurality of first redistribution patterns and the plurality of bump structures, wherein each of the plurality of first redistribution vias has a side surface tapered toward the first surface, and wherein the second portion of the plurality of bump structures has a side surface tapered in a direction away from the first surface.

According to an aspect of the example embodiment, provided is a semiconductor package including a redistribution structure having a first surface and an opposite second surface, wherein the redistribution structure includes an insulating layer, a plurality of redistribution patterns within the insulating layer, and a plurality of redistribution vias extending from the plurality of redistribution patterns in a direction toward the first surface of the redistribution structure; a plurality of bump structures on the first surface of the redistribution structure, and each of the plurality of bump structures including a first portion within the insulating layer and a second portion protruding from the first portion; a plurality of solder bumps, each of the plurality of solder bumps on the second portion of a respective one of the plurality of bump structures; and a semiconductor chip on the second surface of the redistribution structure and electrically connected to the redistribution patterns, wherein the plurality of redistribution vias include a plurality of lower vias in contact with the plurality of bump structures, and a plurality of upper vias, each of the plurality of upper vias on a respective one of the plurality of lower vias, wherein a minimum width of each of the plurality of lower vias is greater than a minimum width of the second portion of each of the plurality of bump structures and a minimum width of each of the plurality of upper vias, and wherein the minimum width of the second portion of the plurality of bump structures is greater than the minimum width of the plurality of upper vias.

According to an aspect of the example embodiment, provided is a semiconductor package including a redistribution structure having a first surface and an opposite second surface, wherein the redistribution structure includes an insulating layer, a plurality of redistribution patterns within the insulating layer, and a plurality of redistribution vias connected to the plurality of redistribution patterns; a plurality of bump structures on the first surface of the redistribution structure, wherein the plurality of bump structures are connected to the plurality of redistribution vias; and a semiconductor chip on the second surface of the redistribution structure, wherein the semiconductor chip is electrically connected to the plurality of redistribution patterns, wherein each of the plurality of bump structures has a first lower surface which is coplanar with the first surface of the redistribution structure, a second lower surface spaced apart from the first lower surface, and a side surface connecting the first lower surface and the second lower surface, and wherein the side surface of each of the plurality of bump structures is tapered in a direction away from the first surface of the redistribution structure.

### BRIEF DESCRIPTION OF DRAWINGS

The above and other aspects, features, and advantages of the present disclosure will be more clearly understood from the following detailed description, taken in conjunction with the accompanying drawings:

FIG. 1A is a cross-sectional view of a semiconductor package according to an example embodiment, FIG. 1B is a partial enlarged view of region A of FIG. 1A, and FIG. 1C is a cross-sectional view taken along line I-I′ of FIG. 1B;

FIG. 2A is a cross-sectional view of a semiconductor package according to an example embodiment, FIG. 2B is a partial enlarged view of region B of FIG. 2A, and FIG. 2C is a cross-sectional view taken along line II-II′ of FIG. 2B;

FIG. 3A is a cross-sectional view of a semiconductor package according to an example embodiment, FIG. 3B is a partial enlarged view of region C of FIG. 3A, and FIG. 3C is a cross-sectional view taken along line III-III′ of FIG. 3B;

FIG. 4A is a cross-sectional view of a semiconductor package according to an example embodiment, FIG. 4B is a partial enlarged view of region D of FIG. 4A, and FIG. 4C is a cross-sectional view along line IV-IV′ of FIG. 4B;

FIG. 5A is a cross-sectional view of a semiconductor package according to an example embodiment, and FIG. 5B is a partial enlarged view of region E of FIG. 5A;

FIG. 6 is a cross-sectional view of a semiconductor package according to an example embodiment;

FIG. 7 is a cross-sectional view of a semiconductor package according to an example embodiment; and

FIGS. 8A to 8N are diagrams for illustrating a manufacturing process of a semiconductor package according to an example embodiment.

### DETAILED DESCRIPTION

Hereinafter, with reference to the accompanying drawings, preferred embodiments will be described as follows. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

In addition, ordinal numbers such as “first,” “second,” “third,” or the like may be used as labels for specific elements, steps, directions, or the like to distinguish various elements, step portions, directions, or the like from each other. Terms that are not described using “first,” “second,” or the like in the specification may still be referred to as “first” or “second” in the claims. In addition, terms referenced by a particular ordinal number (e.g., “first” in a particular claim) may be described elsewhere with a different ordinal number (e.g., “second” in the specification or another claim).

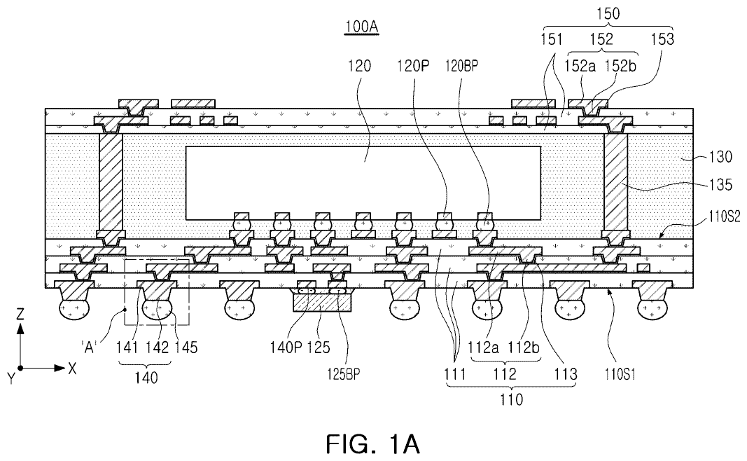

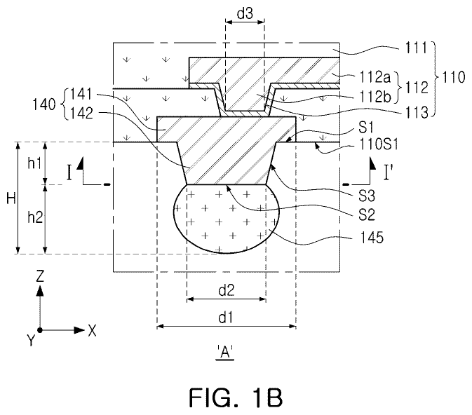

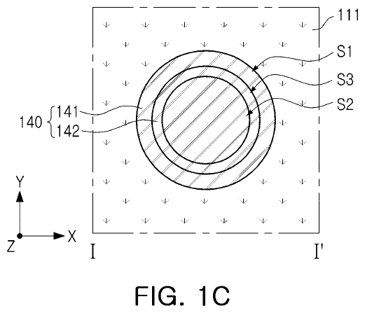

FIG. 1A is a cross-sectional view of a semiconductor package 100A according to an example embodiment, FIG. 1B is a partial enlarged view of region A of FIG. 1A, and FIG. 1C is a cross-sectional view taken along line I-I′ of FIG. 1B.

Referring to FIGS. 1A, 1B, and 1C, a semiconductor package 100A of an example embodiment may include a first redistribution structure 110, a semiconductor chip 120, and bump structures 140. According to an example embodiment, the semiconductor package 100A may further include a mold layer 130, through-vias 135, and a second redistribution structure 150.

The first redistribution structure 110 is a support substrate on which a semiconductor chip 120 is mounted, and may include a first insulating layer 111, first redistribution conductors 112, and a first seed layer 113. In addition, the first redistribution structure 110 may further include a lower pad 140P on which a passive element 125 is mounted. The passive element 125 may be electrically connected to the lower pad 140P by a connection bump 125BP. The passive element 125 can improve Signal Integrity (SI) and/or Power Integrity (PI) characteristics of the semiconductor package. The passive element 125 may include, for example, a capacitor, an inductor, beads, or the like. The passive element 125 may have a thickness smaller than a standoff height of the semiconductor package 100A. Here, the standoff height may be defined as ‘H’ of FIG. 1B.

The first insulating layer 111 may have a first surface 110S1 and a second surface 110S2, opposite to each other, may surround at least a portion of each of the first redistribution conductors 112, and may electrically isolate the first redistribution conductors 112 that are spaced apart from each other. The first surface 110S1 and the second surface 110S2 may be understood as a lower surface and an upper surface of the first redistribution structure 110, respectively. The first insulating layer 111 may include an insulating resin. The insulating resin may include a thermosetting resin such as an epoxy resin, a thermoplastic resin such as a polyimide, or a resin impregnated with an inorganic filler, for example, prepreg, Ajinomoto Build-up Film (ABF), Flame Retardant (FR)-4, or Bismaleimide-Triazine (BT). In an example embodiment, the first insulating layer 111 may include a photosensitive resin such as a Photo-Imageable Dielectric (PID). The first insulating layer 111 may include a plurality of insulating layers stacked in a vertical direction (Z-direction). Depending on the process, a boundary between the plurality of insulating layers may be unclear.

The first redistribution conductors 112 can redistribute the connection pads 120P of the semiconductor chip 120. The first redistribution conductors 112 may include, for example, copper (Cu), aluminum (Al), silver (Ag), tin (Sn), gold (Au), nickel (Ni), lead (Pb), titanium (Ti), or alloys thereof. In an example embodiment, the first redistribution conductors 112 may include copper (Cu) or alloys thereof. The first redistribution conductors 112 may provide a transmission path for power signals, ground signals, data signals, or the like. The first redistribution conductors 112 may be provided in more or fewer layers than those illustrated in the drawings.

The first redistribution conductors 112 may include first redistribution patterns 112a and first redistribution vias 112b. The first redistribution patterns (112a) may be configured to extend in a horizontal direction (X and Y directions) within the first insulating layer 111 to redistribute the connection pads 120P to a fan-out region. The first redistribution conductors 112 may protrude on the second surface 110S2 of the first insulating layer 111, and may include pads connected to the semiconductor chip 120 and through-vias 135. The first redistribution vias 112b may be formed integrally with the first redistribution patterns 112a. The first redistribution vias 112b may be filled vias in which a metal material is filled inside a via hole or conformal vias in which a metal material extends along an inner wall of the via hole. The first redistribution vias 112b may electrically connect the first redistribution patterns 112a spaced apart in a vertical direction (Z-direction). At least a portion of the first redistribution vias 112b may electrically connect the first redistribution patterns 112a to corresponding bump structures 140.

The first seed layer 113 may be disposed along a lower surface of each of the first redistribution conductors 112. The first seed layer 113 may cover at least portions of lower surfaces of the first redistribution patterns 112a and each of lower surfaces and side surfaces of the first redistribution vias 112b. The first seed layer 113 may be formed in the form of a single-layer or multilayer thin film. The first seed layer 113 may include, for example, copper (Cu), aluminum (Al), silver (Ag), tin (Sn), gold (Au), nickel (Ni), lead (Pb) and titanium (Ti), or alloys thereof. In an example embodiment, the first seed layer 113 may include titanium (Ti), copper (Cu), or an alloy of at least one thereof.

The semiconductor chip 120 may be disposed on the second surface 110S2 of the first redistribution structure 110, and may include connection pads 120P electrically connected to the first redistribution conductors 112. The connection pads 120P may be electrically connected to the first redistribution conductors 112 through connection bumps 120BP. The connection bumps 120BP may include a low melting point metal, for example, tin (Sn) or an alloy including tin (Sn). In some example embodiments, the connection bumps 120BP may have a structure in which a metal pillar and a solder ball are combined. According to an example embodiment, an underfill layer surrounding the connection bumps 120BP may be disposed between the semiconductor chip 120 and the first redistribution structure 110. The underfill layer may have a mold underfill (MUF) structure integrated with the mold layer 130, but an example embodiment thereof is not limited thereto. The underfill layer may also have a capillary underfill (CUF) structure.

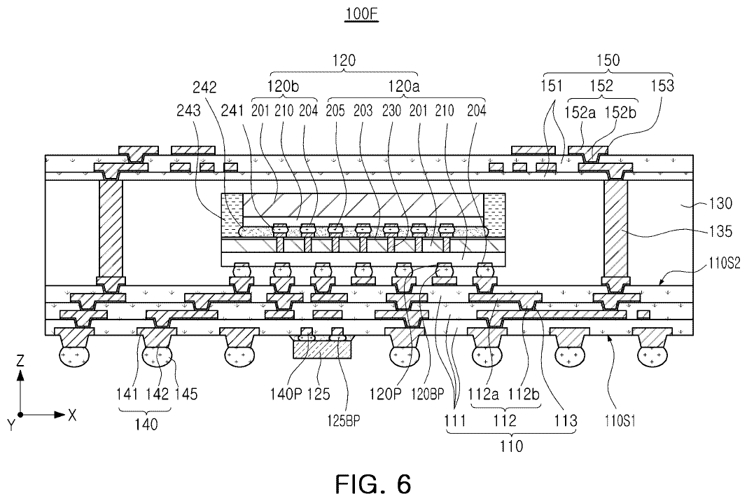

The semiconductor chip 120 may include a semiconductor wafer and an integrated circuit (IC) formed of a semiconductor element such as silicon or germanium, or a compound semiconductor such as silicon carbide (SiC), gallium arsenide (GaAs), indium arsenide (InAs), and indium phosphide (InP). The semiconductor chip 120 may be a bare semiconductor chip without a separate bump or wiring layer formed thereon, but an example embodiment thereof is not limited thereto, and may also be a packaged-type semiconductor chip. According to an example embodiment, the semiconductor chip 120 may be a package structure including a plurality of semiconductor chips, which will be described later with reference to FIG. 6.

The semiconductor chip 120 may include a logic circuit (or ‘logic chip’) such as a central processing unit (CPU), a graphics processing unit (GPU), a field programmable gate array (FPGA), an application processor (AP), a digital signal processor, an encryption processor, a microprocessor, a microcontroller, an analog-to-digital converter, an application-specific IC (ASIC), or a memory circuit (or ‘memory chip’) including volatile memory such as a dynamic RAM (DRAM) and a static RAM (SRAM), and non-volatile memory such as a phase change RAM (PRAM), a magnetic RAM (MRAM), a resistive RAM (RRAM), and a flash memory.

The mold layer 130 may be disposed on the first redistribution structure 110, and may cover at least a portion of each of the semiconductor chip 120 and the through-vias 135. The mold layer 130 may include, for example, a thermosetting resin such as an epoxy resin, a thermoplastic resin such as a polyimide, or a prepreg, ABF, FR-4, BT, Epoxy Molding Compound (EMC), or the like.

The through-vias 135 may be disposed around the semiconductor chip 120 (i.e., the through-vias 135 may be positioned around the periphery of the semiconductor chip 120). The through-vias 135 may electrically connect the first redistribution conductors 112 and the second redistribution conductors 152. The through-vias 135 may include, for example, copper (Cu), aluminum (Al), silver (Ag), tin (Sn), gold (Au), nickel (Ni), lead (Pb), titanium (Ti), or alloys thereof. The through-vias 135 may have a cylindrical shape extending in a vertical direction (Z-direction), but an example embodiment thereof is not limited thereto.

The bump structures 140 may be disposed on the first surface 110S1 of the first redistribution structure 110. The bump structures 140 may be electrically connected to the first redistribution conductors 112. The bump structures 140 may electrically connect the semiconductor chip 120 to an external device such as a module substrate, a main board, or the like. The bump structures 140 may include a material similar to the first redistribution conductors 112. The bump structures 140 may include, for example, copper (Cu), aluminum (Al), silver (Ag), tin (Sn), gold (Au), nickel (Ni), lead (Pb) and titanium (Ti), or alloys thereof.

According to example embodiments, by introducing bump structures 140 isolating the solder bumps 145 and the first redistribution structure 110 by a considerable height, a standoff height of the semiconductor package 100A may be secured, and as a result, a pitch between the solder bumps 145 may be refined and reliability may be improved. The solder bumps 145 may include a low melting point metal, for example, tin (Sn) or an alloy including tin (Sn) (e.g., Sn—Ag—Cu).

The bump structures 140 may include a first portion 141 and a second portion 142. The first portion 141 may be disposed within a first insulating layer 111. The side surface of the first portion 141 may be surrounded by the first insulating layer 111. The first portion 141 may have a first lower surface S1 exposed from the first insulating layer 111. The first lower surface S1 may form a coplanar surface with a first surface 110S1 of the first insulating layer 111. The second portion 142 may extend in a vertical direction (Z-direction) from the first lower surface S1 of the first portion 141. The second portion 142 may protrude from the first portion 141 in a direction away from the first surface 110S1. The second portion 142 may have a second lower surface S2 contacting the solder bumps 145 and a side surface S3 connecting the second lower surface S2 and the first lower surface S1. The second portion 142 may have a shape tapered in the same direction as the first redistribution vias 112b. The first redistribution vias 112b may have a shape in which a side surface is tapered in a direction toward the first surface 110S1. The second portion 142 may have a shape in which the side surface S3 is tapered in a direction away from the first surface 110S1.

In an example embodiment, to implement a fine pitch between solder bumps 145, the second portion 142 may be formed narrower than the first portion 141. A minimum width (d2) of the second portion 142 may be smaller than a minimum width (d1) of the first portion 141. The minimum width (d2) of the second portion 142 may be about 40 μm or more, for example, about 40 μm to about 70 μm, about 40 μm to about 60 μm, or the like, but an example embodiment thereof is not limited thereto. The minimum width (d2) of the second portion 142 may be determined according to the size of the solder bumps 145. The solder bumps 145 may be solder balls having a diameter corresponding to the minimum width (d2) of the second portion 142. For example, when a diameter of the solder bumps 145 is about 50 μm, a gap between adjacent solder bumps 145 may be about 150 μm or less. At least a portion of the first redistribution vias 112b have a size corresponding to a line and space of the first redistribution patterns 112a, and thus may have a narrower shape than the second portion 142. For example, the minimum width (d3) of at least a portion of the first redistribution vias 112b may be smaller than the minimum width (d2) of the second portion 142.

In addition, in order to secure a standoff height of the semiconductor package 100A, the second portion 142 may be formed to have a predetermined height. A height (h1) of the second portion 142 in the vertical direction (Z-direction) may be about 40 μm or more, for example, about 40 μm to about 60 μm, about 40 μm to about 50 μm, or the like, but an example embodiment thereof is not limited thereto. A height (h2) of the solder bumps 145 may be similar to the height (h1) of the second portion 142. The height (h1) of the second portion 142 may be determined by considering a size and pitch of the solder bumps 145 and the required standoff height (H).

The second redistribution structure 150 may be disposed on the mold layer 130, and may include a second insulating layer 151, second redistribution conductors 152, and a second seed layer 153. The second redistribution conductors 152 may include second redistribution patterns 152a and second redistribution vias 152b. Since the second insulating layer 151, the second redistribution conductors 152, and the second seed layer 153 have the same or similar characteristics as the first insulating layer 111, the first redistribution conductors 112, and the first seed layer 113 described above, any duplicate description thereof is omitted.

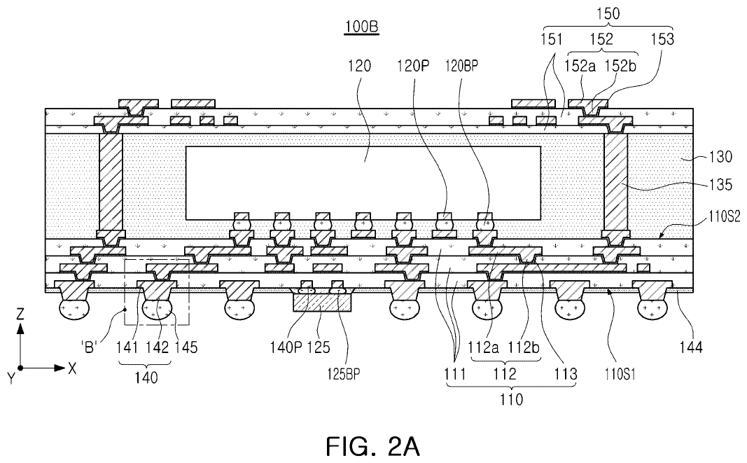

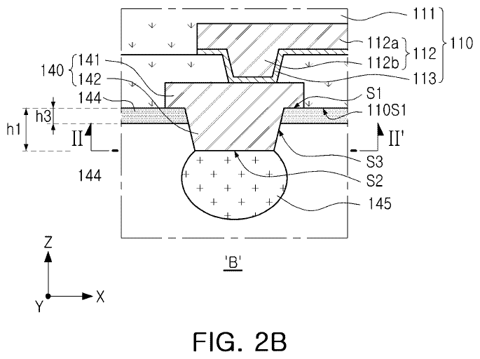

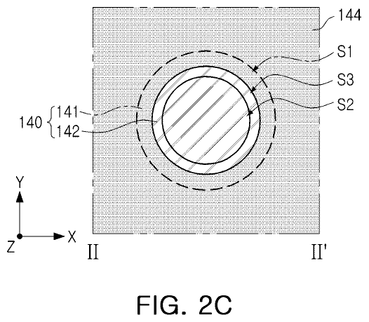

FIG. 2A is a cross-sectional view of a semiconductor package 100B according to an example embodiment, FIG. 2B is a partial enlarged view of region B of FIG. 2A, and FIG. 2C is a cross-sectional view taken along line II-II′ of FIG. 2B.

Referring to FIGS. 2A, 2B, and 2C, the semiconductor package 100B of the example embodiment may have the same or similar features as described with reference to FIGS. 1A to 1C, except for further including a passivation layer 144 covering at least a portion of the bump structures 140. The passivation layer 144 may be disposed on a first surface 110S1 of the first insulating layer 111 (or the first redistribution structure 110). In an example embodiment, the passivation layer 144 may be formed to cover the entire first surface 110S1. The passivation layer 144 may surround a portion of a side surface S3 of the second portion 142 of the bump structures 140. The passivation layer 144 may be in contact with the first surface 110S1 of the first insulating layer 111 and the first lower surface S1 and the side surface S3 of the bump structures 140. The passivation layer 144 may be a solder resist layer which is conformally formed by spin coating, or the like after the passive element 125 is mounted. The passivation layer 144 may include an epoxy-based non-photosensitive resin. The passivation layer 144 may be formed to a thickness that does not excessively reduce a standoff height. A thickness (h3) of the passivation layer 144 may be smaller than a height (h1) of the second portion 142. For example, the thickness (h3) of the passivation layer 144 may be 50% or less of the height (h1) of the second portion 142.

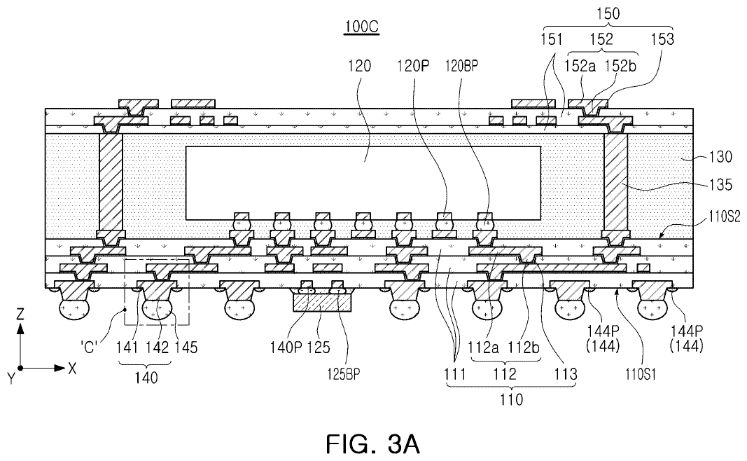

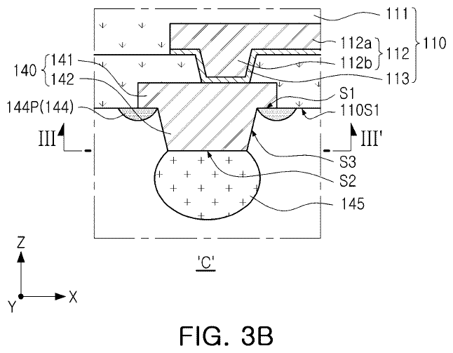

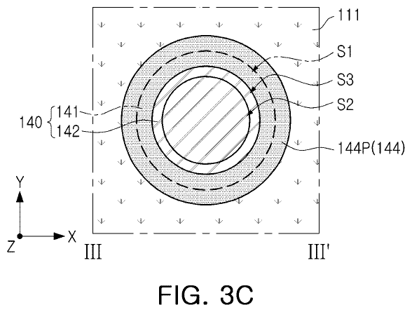

FIG. 3A is a cross-sectional view of a semiconductor package 100C according to an example embodiment, FIG. 3B is a partial enlarged view of region C of FIG. 3A, and FIG. 3C is a cross-sectional view taken along line III-III′ of FIG. 3B.

Referring to FIGS. 3A, 3B, and 3C, the semiconductor package 100C of the example embodiment may have the same or similar features as described with reference to FIGS. 1A to 2C, except for including a plurality of passivation patterns 144P. In an example embodiment, the passivation layer 144 may include a plurality of passivation patterns 144P spaced apart from each other. The passivation patterns 144P may extend along a boundary between a first surface 110S1 of the first insulating layer 111 and a first lower surface S1 of the first portion 141. The passivation patterns 144P may have a ring shape surrounding a side surface S3 of the second portion 142. The passivation patterns 144P may be in contact with the first surface 110S1 of the first insulating layer 111 and the first lower surface S1 and the side surface S3 of the bump structures 140. In some example embodiments, the passivation patterns 144P may be spaced apart from the side surface S3 of the second portion 142. The passivation patterns 144P may be a solder resist layer distributed around a periphery of the second portion 142.

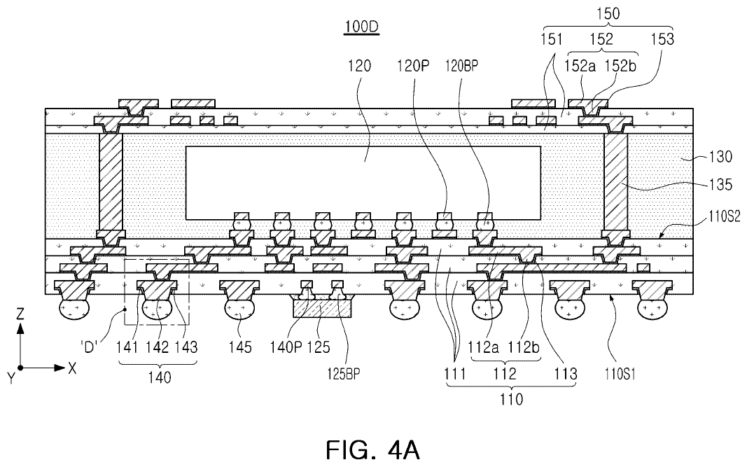

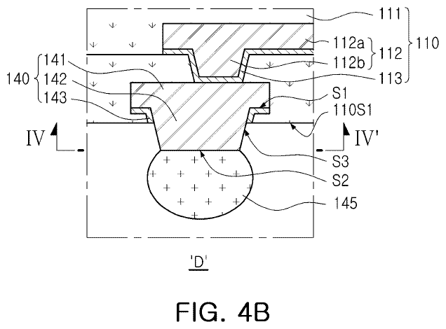

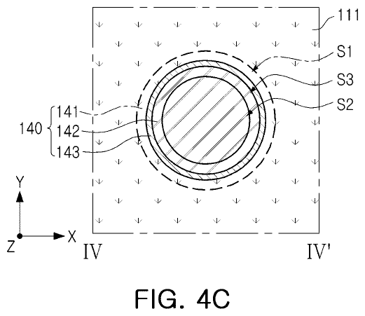

FIG. 4A is a cross-sectional view of a semiconductor package 100D according to an example embodiment, FIG. 4B is a partial enlarged view of region ‘D’ of FIG. 4A, and FIG. 4C is a cross-sectional view taken along line IV-IV′ of FIG. 4B.

Referring to FIGS. 4A, 4B, and 4C, the semiconductor package 100D of the example embodiment may have the same or similar features as described with reference to FIGS. 1A to 3C, except for further including a barrier layer 143 covering bump structures 140.

In an example embodiment, the first insulating layer 111 may cover a portion of a first lower surface S1 of the first portion 141 and a portion of a side surface S3 of the second portion 142. A first surface 110S1 of the first insulating layer 111 may be disposed between the first lower surface S1 and the second lower surface S2. A gap between the first surface 110S1 and the first lower surface S1 may be smaller than a gap between the first surface 110S1 and the second lower surface S2. The gap between the first surface 110S1 and the first lower surface S1 may be 50% or less of the gap between the first surface 110S1 and the second lower surface S2.

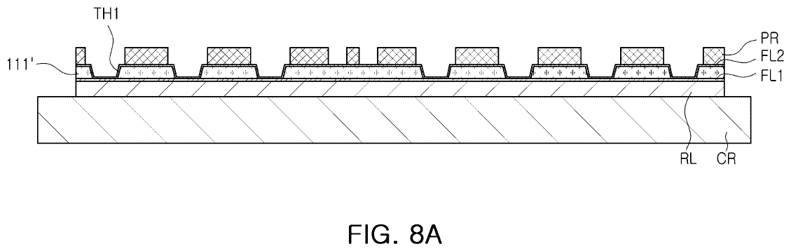

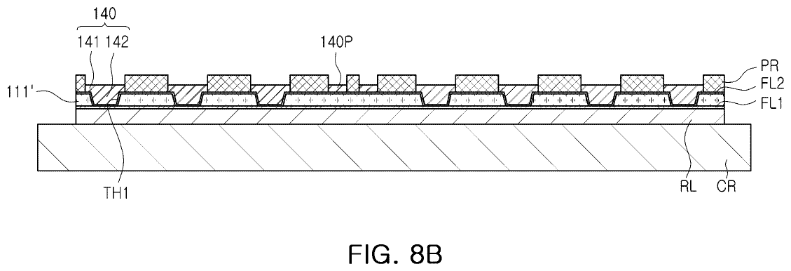

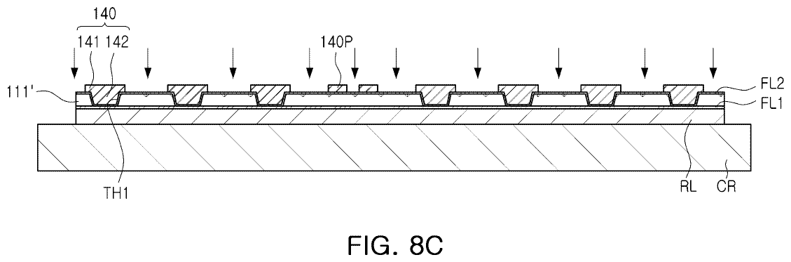

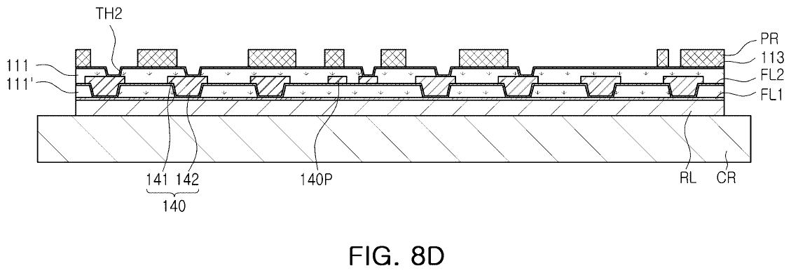

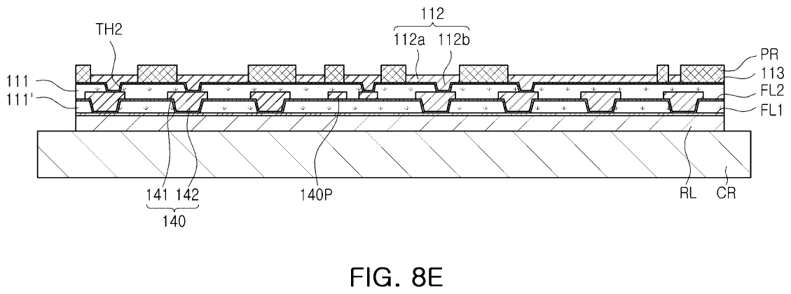

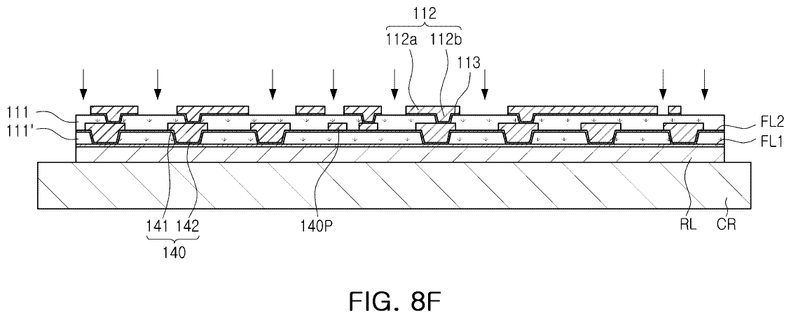

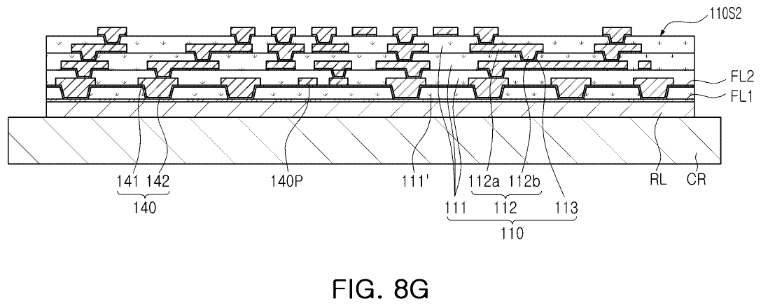

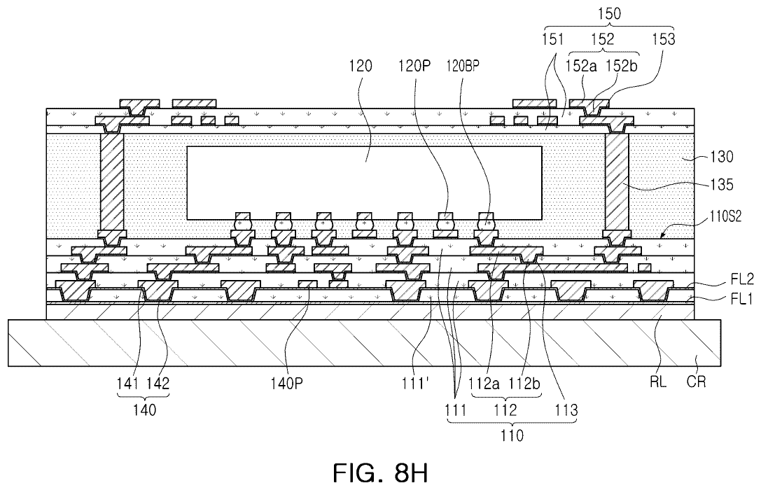

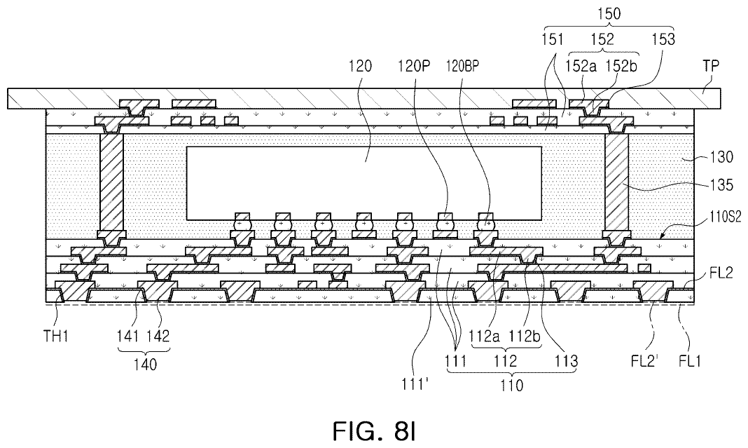

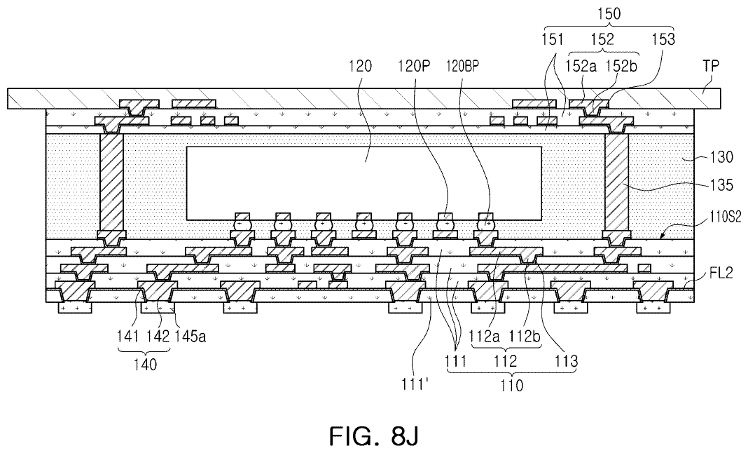

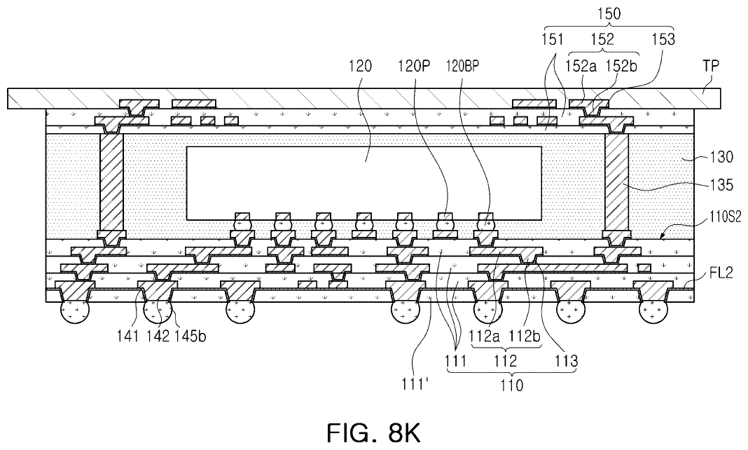

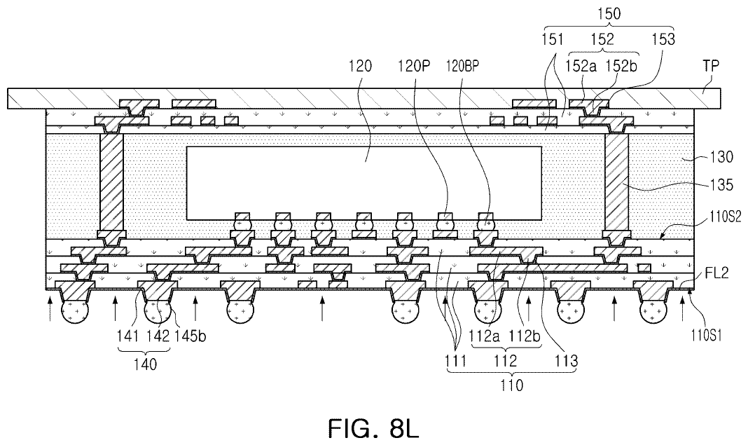

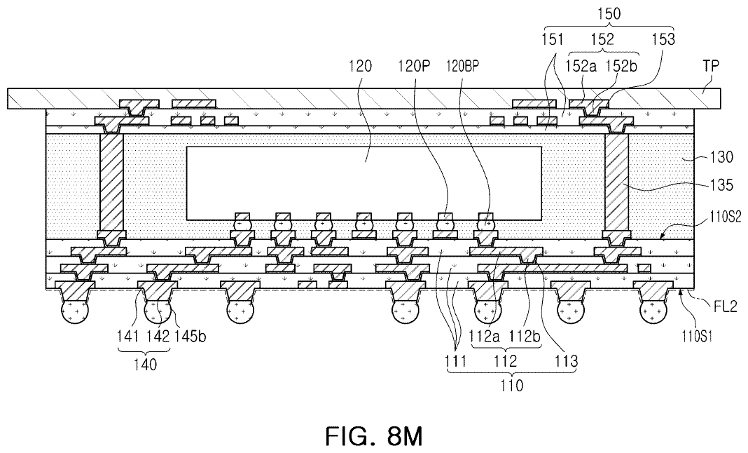

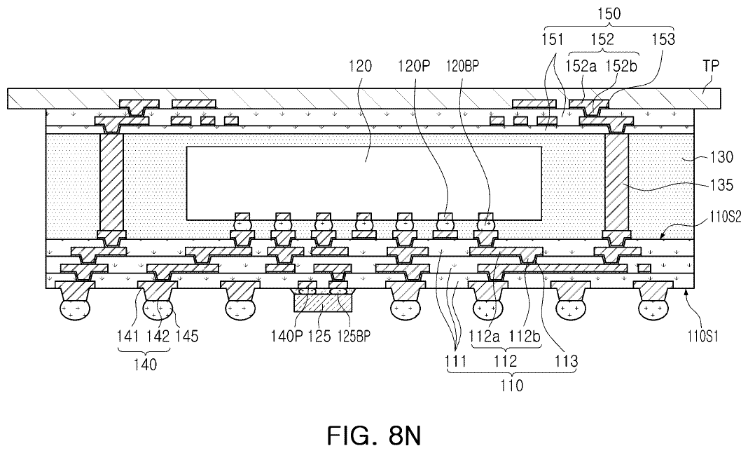

The bump structures 140 may further include a barrier layer 143 disposed between the first insulating layer 111 and the first lower surface S1 and between the first insulating layer 111 and the side surface S3 of the second portion 142. The barrier layer 143 may include titanium (Ti), copper (Cu), or an alloy of at least one thereof. The barrier layer 143 may be a residual portion of a plating seed layer (second thin film layer FL2) used to form the first portion 141 and the second portion 142. A method of forming the barrier layer 143 is described with reference to FIGS. 8C, 8L, 8M, or the like.

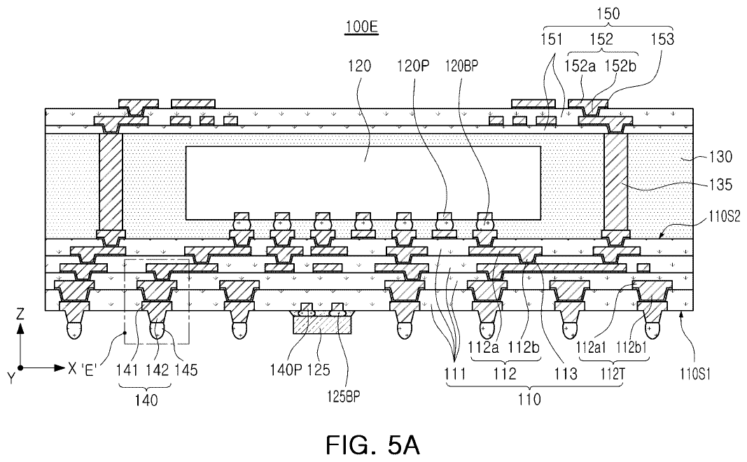

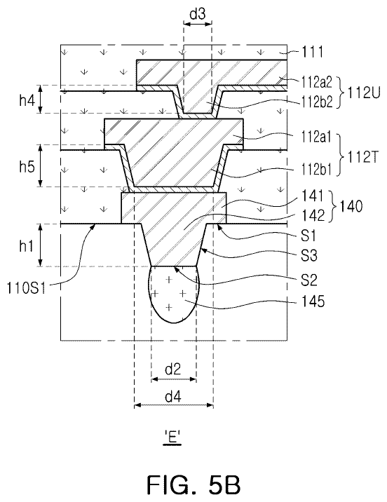

FIG. 5A is a cross-sectional view of a semiconductor package 100E according to an example embodiment, and FIG. 5B is a partial enlarged view of region E of FIG. 5A.

Referring to FIGS. 5A and 5B, the semiconductor package 100E of the example embodiment may have the same or similar features as described with reference to FIGS. 1A to 4C, except for further including lower redistribution conductors 112T connecting the bump structures 140 and the redistribution conductors 112. In an example embodiment, the first redistribution conductors 112 may include lower redistribution conductors 112T and upper redistribution conductors 112U.

The lower redistribution conductors 112T may include lower patterns 112a1 and lower vias 112b1. The upper redistribution conductors 112U may include upper patterns 112a2 and upper vias 112b2. The lower vias 112b1, the upper vias 112b2, and the second portion 142 may have shapes in which side surfaces are tapered in the same direction. The lower patterns 112a1 and the upper patterns 112a2 may include features similar to the first redistribution patterns 112a described with reference to FIGS. 1A to 1C, and the lower vias 112b1 and the upper vias 112b2 may include features similar to the first redistribution vias 112b described with reference to FIGS. 1A to 1C. In the present specification, the upper redistribution conductors 112U may be referred to as first redistribution conductors 112, and the upper patterns 112a2 and upper vias 112b2 may be referred to as first redistribution patterns 112a and first redistribution vias 112b, respectively.

The lower patterns 112a1 may be connected to the upper vias 112b2, and the lower vias 112b1 may be connected to a first portion 141 of the bump structures 140. The lower redistribution conductors 112T may improve the connection reliability between the bump structures 140 and the first redistribution conductors 112. A minimum width (d4) of the lower vias 112b1 may be greater than a minimum width (d2) of the second portion 142 and a minimum width (d3) of the upper vias 112b2. The minimum width (d2) of the second portion 142 may be greater than the minimum width (d3) of the upper vias 112b2. The minimum width (d4) of the lower vias 112b1 may be approximately 100 μm or more, but an example embodiment thereof is not limited thereto.

FIG. 6 is a cross-sectional view of a semiconductor package 100F according to an example embodiment.

Referring to FIG. 6, the semiconductor package 100F of the example embodiment may have the same or similar features as those described with reference to FIGS. 1A to 5B, except for including a chip structure 120 having a plurality of semiconductor chips 120a and 120b embedded therein.

At least a portion of the plurality of semiconductor chips 120a and 120b (e.g., ‘120a’) may include through-hole electrodes 230 electrically connecting the plurality of semiconductor chips 120a and 120b to each other. The plurality of semiconductor chips 120a and 120b may be chiplets comprising a multi-chip module (MCM). The plurality of semiconductor chips 120a and 120b may include a central processor (CPU), a graphics processor (GPU), a field programmable gate array (FPGA), a digital signal processor (DSP), an encryption processor, a microprocessor, a microcontroller, an analog-to-digital converter, an application-specific integrated circuit (ASIC), a volatile memory, a non-volatile memory, an input/output (I/O) circuit, an analog circuit, a serial-to-parallel conversion circuit, and the like.

In an example embodiment, the chip structure 120 may include a base chip 120a and at least one stacked chip 120b. For example, the base chip 120a may include a processor circuit, and the at least one stacked chip 120b may include at least one of an input/output circuit, an analog circuit, a memory circuit, and a serial-to-parallel conversion circuit for the processor circuit. The base chip 120a and at least one stacked chip 120b may be provided in a greater number than that shown in the drawing. For example, the at least one stacked chip 120b may include two or more semiconductor chips disposed horizontally and/or vertically on the base chip 120a.

The base chip 120a and the stacked chip 120b may include a substrate 201, an upper protective layer 203, an upper pad 205, a circuit layer 210, a lower pad 204, and/or a through-electrode 230. The substrate 201 may include, for example, a semiconductor element such as silicon or germanium (Ge), or a compound semiconductor such as silicon carbide (SiC), gallium arsenide (GaAs), indium arsenide (InAs), or indium phosphide (InP). The substrate 201 may have a challenge region, such as a well doped with impurities, or an active surface doped with impurities and an inactive surface opposite thereto. The substrate 201 may include various device isolation structures, such as a shallow trench isolation (STI) structure.

The upper protective layer 203 is formed on the inactive surface of the substrate 201, and can protect the substrate 201. The upper protective layer 203 may be formed as an insulating layer such as a silicon oxide film, a silicon nitride film, a silicon oxynitride film, or the like, but a material of the upper protective layer 203 is not limited to the above-described materials. Although not shown in the drawing, a lower protective layer can be further formed on a lower surface of the circuit layer 210.

The upper pad 205 may be disposed on the upper protective layer 203. The upper pad 205 may include, for example, at least one of aluminum (Al), copper (Cu), nickel (Ni), tungsten (W), platinum (Pt), and gold (Au). The lower pad 204 may be disposed below the circuit layer 210, and may include a material similar to the upper pad 205. However, the materials of the upper pad 205 and the lower pad 204 are not limited to the above-described materials. The lower pad 204 of the base chip 120a may be understood to correspond to the above-described connection pads 120P.

The circuit layer 210 may be disposed on the active surface of the substrate 201, and may include various types of elements. For example, the circuit layer 210 may include various active elements and/or passive elements, such as FETs such as Planar Field Effect Transistors (FETs) or FinFETs, memory elements such as flash memory, Dynamic Random Access Memory (DRAMs), Static Random Access Memory (SRAMs), Electrically Erasable Programmable Read-Only Memory (EEPROMs), Phase-change Random Access Memory (PRAMs), Magnetoresistive Random Access Memory (MRAMs), Ferroelectric Random Access Memory (FeRAMs), and Resistive Random Access Memory (RRAMs), logic elements such as ANDs, ORs, and NOTs, and system Large Scale Integration (LSIs), CMOS Imaging Sensors (CISs), and Micro-Electro-Mechanical Systems (MEMSs). The circuit layer 210 may include a wiring structure electrically connected to the above-described elements and an interlayer insulating layer surrounding the wiring structure. The interlayer insulating layer may include silicon oxide or silicon nitride. The wiring structure may include multilayer wiring and/or vertical contacts. The wiring structure may connect elements of the circuit layer 210 to each other, connect elements to a conductive region of the substrate 201, or connect elements to through-electrodes 230.

The circuit layer 210 may include a wiring structure electrically connected to the above-described elements and an interlayer insulating layer surrounding the wiring structure. The interlayer insulating layer may include silicon oxide or silicon nitride. The wiring structure may include multilayer wiring and/or vertical contacts. The wiring structure may connect elements of the circuit layer 210 to each other, connect elements to a conductive region of the substrate 201, or connect elements to through-electrodes 230. The through-electrode 230 may include, for example, tungsten (W), titanium (Ti), aluminum (Al), or copper (Cu). The through-electrode 230 may be formed by a plating process, a PVD process, or a CVD process.

The base chip 120a and at least one stacked chip 120b may be electrically connected through bumps 241. The bumps 241 may be disposed within an adhesive layer 242 between the base chip 120a and at least one stacked chip 120b. The bumps 241 may include tin (Sn), indium (In), bismuth (Bi), antimony (Sb), copper (Cu), silver (Ag), zinc (Zn), lead (Pb), and/or alloys thereof, and may have a form in which a metal pillar and a solder ball are combined, depending on the example embodiment. The adhesive layer 242 may surround each of the bumps 241, and may bond the base chip 120a and at least one stacked chip 120b. The adhesive layer 242 may be formed using a NCF (Non-Conductive Film), but an example embodiment thereof is not limited thereto, and may be formed by any type of insulating film that can be subjected to a thermocompression process, for example. In some example embodiments, the base chip 120a and at least one stacked chip 120b may be directly bonded and connected to the corresponding upper pad 205 and lower pad 204 without bumps 241.

At least one stacked chip 120b may be sealed by a mold 243. The mold 243 may surround an outer surface of the adhesive layer 242 and the at least one stacked chip 120b on the base chip 120a. The mold 243 may include an insulating material, such as EMC, for example.

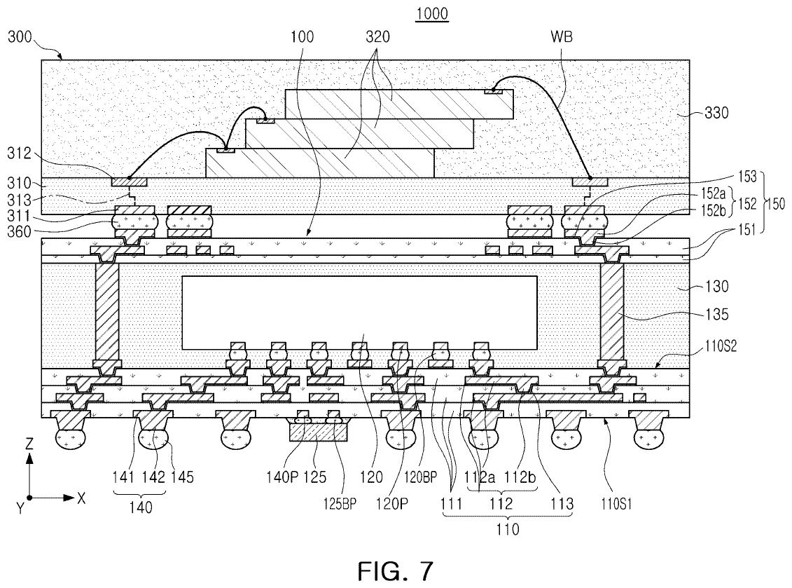

FIG. 7 is a cross-sectional view of a semiconductor package 1000 according to an example embodiment.

Referring to FIG. 7, the semiconductor package 1000 of the example embodiment may include a lower package 100 and an upper package 300. The lower package 1000 is illustrated in the same manner as the semiconductor package 100A illustrated in FIG. 1A, but may be replaced with semiconductor packages 100A, 100B, 100C, 100D, 100E, and 100F having similar characteristics as those described with reference to FIGS. 1A to 6. The semiconductor package 1000 of the present embodiment includes a lower package 100 into which bump structures 140 are introduced, and may implement a package-on-package structure with improved reliability.

The upper package 300 may include a wiring board 310, a semiconductor chip 320, and an encapsulant 330. The wiring board 310 may include a lower pad 311 and an upper pad 312. In addition, the wiring board 310 may include a wiring circuit 313 electrically connecting the lower pad 311 and the upper pad 312. The wiring board 310 may be a semiconductor package board including a printed circuit board (PCB), a ceramic substrate, a glass substrate, a tape wiring board, or the like. For example, the wiring board 310 may be a double-sided printed circuit board (double-sided PCB) or a multilayer printed circuit board (multilayer PCB).

The semiconductor chip 320 may be mounted on the wiring board 310 by wire bonding or flip-chip bonding. For example, a plurality of semiconductor chips 320 may be stacked vertically on the wiring board 310 and electrically connected to the upper pad 312 of the wiring board 310 by bonding wires WB. In an example, the semiconductor chip 320 of the upper package 300 may include a memory chip, and the chip structure 120 of the lower package 100 may include an AP chip.

The encapsulant 330 may include a material, which is the same as or similar to a mold layer 130 of the lower package 100. The upper package 300 may be physically and electrically connected to the lower package 100 by a conductive bump 360. The conductive bump 360 may include a low-melting point metal, for example, tin (Sn) or an alloy including tin (Sn).

FIGS. 8A to 8N are diagrams illustrating a manufacturing process of a semiconductor package 100A of an example embodiment.

Referring to FIG. 8A, a first thin film layer FL1, a temporary insulating layer 111′, and a second thin film layer FL2 may be sequentially formed on a carrier substrate CR. The carrier substrate CR may be a temporary support including a glass wafer, a curable resin layer, or the like. The first thin film layer FL1 may be conformally formed on a surface of a release layer RL by a deposition process. The temporary insulating layer 111′ may be formed using a photosensitive resin such as PID. The temporary insulating layer 111′ may include first via holes TH1 formed by a photolithography process. The second thin film layer FL2 may be conformally formed along a surface of the temporary insulating layer 111′ by a deposition process. The first thin film layer FL1 may be a single layer containing titanium (Ti), and the second thin film layer FL2 may be a double layer containing titanium (Ti) and copper (Cu). A photosensitive material layer PR patterned by a photolithography process may be formed on the second thin film layer FL2.

Referring to FIG. 8B, bump structures 140 and lower pads 140P may be formed. The bump structures 140 and the lower pads 140P may be formed by a plating process using the second thin film layer FL2 as a seed. The bump structures 140 and the lower pads 140P may include copper (Cu) or alloys thereof. Thereafter, the photosensitive material layer PR may be removed by an ashing process.

Referring to FIG. 8C, a portion of the second thin film layer FL2 may be removed. A surface layer (e.g., copper (Cu) layer) of the second thin film layer FL2 exposed after the photosensitive material layer PR may be removed by an etching process. Only a base layer (e.g., titanium (Ti) layer) of the second thin film layer FL2 having etch selectivity with respect to the surface layer (e.g., copper (Cu) layer) of the second thin film layer FL2 may remain between bump structures 140. In some example embodiments, the second thin film layer FL2 exposed between the bump structures 140 may be entirely removed (e.g., example embodiments of FIGS. 4A to 4C).

Referring to FIG. 8D, a first insulating layer 111 and a first seed layer 113 may be formed. The first insulating layer 111 may be formed using a photosensitive resin such as PID. The first insulating layer 111 may include second via holes (TH2) formed by a photolithography process. The first seed layer 113 may be conformally formed along a surface of the first insulating layer 111 by a deposition process. The first seed layer 113 may be a double layer including titanium (Ti) and copper (Cu). A photosensitive material layer (PR) for forming first redistribution conductors may be formed on the first seed layer 113.

Referring to FIG. 8E, first redistribution conductors 112 may be formed. The first redistribution conductors 112 may include first redistribution patterns 112a on the first insulating layer 111 and first redistribution vias 112b within the second via holes (TH2). The first redistribution conductors 112 may be formed by a plating process using the first seed layer 113 as a seed. The first redistribution conductors 112 may include copper (Cu) or alloys thereof. Thereafter, the photosensitive material layer (PR) may be removed by an ashing process.

Referring to FIG. 8F, a portion of the first seed layer 113 may be removed. Exposed regions of the first seed layer 113 exposed between the first redistribution conductors 112 may be completely removed by an etching process. The first seed layer 113 may exist only on a lower surface of each of the first redistribution conductors 112, and may be physically and electrically separated in a horizontal direction.

Referring to FIG. 8G, a first redistribution structure 110 may be formed by repeating the above-described process (FIGS. 8D to 8F). The first redistribution structure 110 may include a first insulating layer 111, first redistribution conductors 112, and a first seed layer 113. The first redistribution conductors 112 may include upper pads protruding on the second surface 110S2 of the first insulating layer 111. Thereafter, through-vias 135 may be formed on the first redistribution structure 110, and a semiconductor chip 120 may be mounted (see FIG. 8H).

Referring to FIG. 8H, a mold layer 130 and a second redistribution structure 150 may be formed. The mold layer 130 may seal the semiconductor chip 120 and the through-vias 135. The mold layer 130 may be formed by applying and curing a molding material such as EMC. The semiconductor chip 120 may be mounted in a flip-chip manner. The semiconductor chip 120 may be connected to the first redistribution conductors 112 by a connection bump 120BP. The second redistribution structure 150 may include a second insulating layer 151, second redistribution conductors 152, and a second seed layer 153. The second redistribution structure 150 may be formed by repeating a process similar to the first redistribution structure 110. Thereafter, a carrier substrate (CR) may be removed, and a support tape (TP) may be attached on the second redistribution structure 150 (see FIG. 8I).

Referring to FIG. 8I, a first thin film layer FL1 exposed after the carrier substrate (CR) is removed may be removed. The first thin film layer FL1 may be removed by a wet etching process. In addition, a portion of the second thin film layer FL2 exposed through a first via hole TH1 of a temporary insulating layer 111′ (FL2′) may be etched together with the first thin film layer FL1. The bump structures 140 may include a first thin film layer FL1 and a second thin film layer FL2, and a material (e.g., copper (Cu)) having an etching selectivity. A second portion 142 of the bump structures 140 may be exposed through the first via hole TH1.

Referring to FIG. 8J, a first preliminary solder bump 145a may be formed on the second portion 142 of the bump structures 140. The first preliminary solder bump 145a may be formed, for example, by stencil printing a solder paste. Considering a subsequent process (reflow process), the first preliminary solder bump 145a may be formed to have a width greater than a width of the first via hole TH1.

Referring to FIG. 8K, a first reflow process may be performed to form a second preliminary solder bump 145b. The second preliminary solder bump 145b may be wetted on a surface of the second portion 142 of the bump structures 140 and may be aggregated into a spherical shape. By the first reflow process, an overlapping region between the temporary insulating layer 111′ and the second preliminary solder bump 145b in a vertical direction may be minimized, and a subsequent process of removing the temporary insulating layer 111′ may be performed more easily.

Referring to FIG. 8L, a temporary insulating layer 111′ may be removed. The temporary insulating layer 111′ may be removed by a dry etching process. A second thin film layer FL2 may be used as an etch stop layer. The second portion 142 of the bump structures 140 may be protruded on a first surface 110S1 of the first redistribution structure 110. In some example embodiments, when the second thin film layer FL2 is not used as an etch stop layer, the temporary insulating layer 111′may remain on the first surface 110S1 of the first redistribution structure 110 to a predetermined thickness (example embodiments of FIGS. 4A to 4C).

Referring to FIG. 8M, a second thin film layer FL2 may be removed. The second thin film layer FL2 may be removed by a wet etching process. After the second thin film layer FL2 is removed, the surfaces of the bump structures 140 and the first insulating layer 111 may be exposed. The bump structures 140 may include a second thin film layer FL2 (e.g., titanium (Ti)) and a material having an etch selectivity (e.g., copper (Cu)). In some example embodiments, when the temporary insulating layer 111′remains, the second thin film layer FL2 may remain partially between the bump structures 140 and the temporary insulating layer 111′ (e.g., example embodiments of FIGS. 4A to 4C).

Referring to FIG. 8N, a second reflow process may be performed to form solder bumps 145. The solder bumps 145 may be aggregated into a spherical shape on the surface of the second portion 142 of the bump structures 140. In some example embodiments, a passive element 125 may be mounted on the lower pad 140P of the first redistribution structure 110. As described above, according to an example embodiment, by introducing the bump structures 140 extended to a lower portion of the first redistribution structure 110, a semiconductor package for securing a standoff height and implementing a fine pitch of solder bumps 145 may be provided.

As set forth above, according to example embodiments of the present inventive concept, a semiconductor package having improved reliability may be provided by introducing bump structures isolating a redistribution structure and solder bumps.

The various and advantageous advantages and effects of the example embodiment are not limited to the above description, and may be more easily understood in the course of describing the specific embodiments of the example embodiment. While example embodiments have been shown and described above, it will be apparent to those skilled in the art that modifications and variations could be made without departing from the scope of the example embodiment, as defined by the appended claims.

While example embodiments have been shown and described above, it will be apparent to those skilled in the art that modifications and variations could be made without departing from the scope of the example embodiment as defined by the appended claims.

What is claimed is:

1. A semiconductor package, comprising:
a first redistribution structure having a first surface and an opposite second surface, wherein the first redistribution structure comprises an insulating layer and a plurality of first redistribution conductors at least partially surrounded by the insulating layer;
a plurality of bump structures on the first surface of the first redistribution structure, wherein each of the plurality of bump structures comprises a first portion surrounded by the insulating layer and a second portion protruding from the first portion in a direction away from the first surface of the first redistribution structure;
a plurality of solder bumps, each of the plurality of solder bumps on the second portion of a respective one of the plurality of bump structures;
a semiconductor chip on the second surface of the first redistribution structure, wherein the semiconductor chip comprises a plurality of connection pads electrically connected to the plurality of first redistribution conductors;
a plurality of through-vias positioned around the semiconductor chip, wherein the plurality of through-vias are electrically connected to the plurality of first redistribution conductors;
a mold layer sealing the semiconductor chip and the plurality of through-vias; and
a second redistribution structure on the mold layer, wherein the second redistribution structure comprises a plurality of second redistribution conductors electrically connected to the plurality of through-vias,
wherein the plurality of first redistribution conductors comprise a plurality of first redistribution patterns and a plurality of first redistribution vias electrically connecting the plurality of first redistribution patterns and the plurality of bump structures,
wherein each of the plurality of first redistribution vias has a side surface tapered toward the first surface of the first redistribution structure, and
wherein the second portion of each of the plurality of bump structures has a side surface tapered in a direction away from the first surface of the first redistribution structure.

2. The semiconductor package of claim 1, wherein a minimum width of the second portion of each of the plurality of bump structures is smaller than a minimum width of the first portion of each of the plurality of bump structures.

3. The semiconductor package of claim 2, wherein the minimum width of the second portion is in a range of about 40 μm to about 70 μm.

4. The semiconductor package of claim 1, wherein a minimum width of each of the plurality of first redistribution vias is smaller than a minimum width of the second portion of each of the plurality of bump structures.

5. The semiconductor package of claim 1, wherein a height of the second portion of each of the plurality of bump structures and a height of each of the plurality of solder bumps in a direction perpendicular to the first surface of the first redistribution structure are in a range of about 40 μm to about 60 μm, respectively.

6. The semiconductor package of claim 1, wherein the first redistribution structure further comprises a plurality of seed layers, wherein a respective one of the plurality of seed layers is below each of the plurality of first redistribution conductors.

7. The semiconductor package of claim 6, wherein the plurality of seed layers comprise titanium (Ti), copper (Cu) or an alloy of at least one thereof,
wherein the plurality of first redistribution conductors and the plurality of bump structures comprise copper (Cu) or alloys thereof, and
wherein the plurality of solder bumps comprise tin (Sn) or alloys thereof.

8. The semiconductor package of claim 1, wherein each of the plurality of bump structures has a first lower surface of the first portion and a second lower surface of the second portion, wherein the second lower surface of the second portion is in contact with a respective one of the plurality of solder bumps.

9. The semiconductor package of claim 8, wherein the first lower surface is coplanar with the first surface of the first redistribution structure.

10. The semiconductor package of claim 8, wherein the insulating layer is on the first lower surface of the first portion and a portion of a side surface of the second portion, and
wherein each of the plurality of bump structures further comprises a barrier layer between the insulating layer and the first lower surface and between the insulating layer and the portion of the side surface of the second portion.

11. The semiconductor package of claim 8, further comprising:
a passivation layer on the first lower surface of the first portion and the first surface of the first redistribution structure.

12. The semiconductor package of claim 11, wherein the passivation layer is on the entire first surface of the first redistribution structure, and surrounds a side surface of the second portion.

13. The semiconductor package of claim 11, wherein the passivation layer comprises a plurality of passivation patterns spaced apart from each other and extending along a boundary between the first lower surface and the first surface of the first redistribution structure.

14. The semiconductor package of claim 11, wherein the insulating layer comprises a photosensitive resin, and wherein the passivation layer comprises a non-photosensitive resin.

15. The semiconductor package of claim 1, wherein a lower redistribution conductor among the plurality of first redistribution conductors comprises a plurality of lower patterns in contact with the plurality of first redistribution vias, and a plurality of lower vias connecting the plurality of lower patterns and the plurality of bump structures, and
wherein a minimum width of each of the plurality of lower vias is greater than a minimum width of the second portion and a minimum width of each of the plurality of first redistribution vias.

16. The semiconductor package of claim 15, wherein the minimum width of each of the plurality of lower vias is about 100 μm or more.

17. A semiconductor package, comprising:
a redistribution structure having a first surface and an opposite second surface, wherein the redistribution structure comprises an insulating layer, a plurality of redistribution patterns within the insulating layer, and a plurality of redistribution vias extending from the plurality of redistribution patterns in a direction toward the first surface of the redistribution structure;
a plurality of bump structures on the first surface of the redistribution structure, and each of the plurality of bump structures comprising a first portion within the insulating layer and a second portion protruding from the first portion;
a plurality of solder bumps, each of the plurality of solder bumps on the second portion of a respective one of each of the plurality of bump structures; and
a semiconductor chip on the second surface of the redistribution structure, and electrically connected to the plurality of redistribution patterns,
wherein the plurality of redistribution vias include a plurality of lower vias, each of the plurality of lower vias in contact with a respective one of the plurality of bump structures, and a plurality of upper vias, each of the plurality of upper vias on a respective one of the plurality of lower vias,
wherein a minimum width of each of the plurality of lower vias is greater than a minimum width of the second portion of each of the plurality of bump structures and a minimum width of each of the plurality of upper vias, and
wherein the minimum width of the second portion of each of the plurality of bump structures is greater than the minimum width of each of the plurality of upper vias.

18. The semiconductor package of claim 17, wherein a lower surface of the first portion of each of the plurality of bump structures is coplanar with the first surface of the redistribution structure.

19. The semiconductor package of claim 17, wherein the plurality of lower vias, the plurality of upper vias, and the second portion of each of the plurality of bump structures have a shape in which respective side surfaces are tapered in a same direction.

20. A semiconductor package, comprising:
a redistribution structure having a first surface and an opposite second surface, wherein the redistribution structure comprises an insulating layer, a plurality of redistribution patterns within the insulating layer, and a plurality of redistribution vias connected to the plurality of redistribution patterns;
a plurality of bump structures on the first surface of the redistribution structure, wherein the plurality of bump structures are connected to the plurality of redistribution vias; and
a semiconductor chip on the second surface of the redistribution structure, wherein the semiconductor chip is electrically connected to the plurality of redistribution patterns,
wherein each of the plurality of bump structures comprises a first lower surface which is coplanar with the first surface of the redistribution structure, a second lower surface spaced apart from the first lower surface, and a side surface connecting the first lower surface and the second lower surface, and
wherein the side surface of each of the plurality of bump structures is tapered in a direction away from the first surface of the redistribution structure.
